(19) United States
(12) Patent Application Publication
(10) Pub. No.: US 2011/0018595 A1
(43) Pub. Date: Jan. 27, 2011

(54) METASTABILITY HARDENED SYNCHRONIZER CIRCUIT

(75) Inventor: Sonal Rattnam SARTHI, Bangalore (IN)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/508,577

(22) Filed: Jul. 24, 2009

(51) Int. Cl. H03L 7/00; H03K 3/289

(52) U.S. Cl. 327/153; 327/141; 327/202

(57) ABSTRACT

A metastability hardened synchronizer circuit includes a plurality of transmission gates, each transmission gate responsive to an input signal and a clock signal to generate a driver signal. The synchronizer circuit also includes a plurality of latches. The plurality of latches includes a first one of the latches in electrical communication with any one of the plurality of transmission gates and responsive to a driver signal to resolve to a stable state and a second one of the latches in electrical communication with another transmission gate of the plurality of transmission gates and responsive to another driver signal to resolve to the stable state.

### TECHNICAL FIELD

Embodiments of the disclosure relate to the field of a synchronizer circuit.

### BACKGROUND

A synchronizer circuit including flip-flops is used for synchronizing an asynchronous input signal with a system clock signal. A flip-flop requires an input signal to have minimal setup time relative to the system clock signal. Setup time is the time for which the input signal should remain stable before the system clock signal transitions from HI to LO or LO to HI. The input signal should also remain stable for a minimum hold time, after the system clock signal transitions, to allow an output signal to achieve state equivalent to that of the input signal. Often, the asynchronous signal can result in violation of the setup time or the hold time which causes the output signal to behave unpredictably and can also cause delay in settling of the output signal to a stable state. The delay can extend to infinite period and is referred to as problem of metastability in the flip-flops. The metastability in the flip-flops can cause the synchronizer circuit to malfunction which in turn can result in failure of a system. The metastability also decreases mean time between failures (MTBF) of the system which should typically be high.

Currently, the problem of the failure of the system due to metastability is solved by waiting for the synchronizer circuit to reach a stable state on its own. However, such a process is time inefficient.

### SUMMARY

Embodiments of the disclosure provide a synchronizer circuit and a method of synchronizing an asynchronous input signal with a clock signal.

An example of a synchronizer circuit includes a plurality of transmission gates. Each transmission gate is responsive to an input signal and a clock signal to generate a driver signal. The synchronizer circuit also includes a plurality of latches. The plurality of latches includes a first one of the latches in electrical communication with any one of the plurality of transmission gates and responsive to a driver signal to resolve to a stable state and a second one of the latches in electrical communication with another transmission gate of the plurality of transmission gates and responsive to a driver signal to resolve to the same stable state.

Another example of a synchronizer circuit includes a first transmission gate responsive to an input signal, and a first and second clock signals to provide a first driver signal. The synchronizer circuit also includes a second transmission gate responsive to the input signal, and the first and second clock signals to provide a second driver signal. Further, the synchronizer circuit includes a first pair of latches in communication with the first transmission gate. A first latch of the first pair of latches is responsive to a logic LO level of the first driver signal to latch into a first stable state. A second latch of the first pair of latches is responsive to a logic HI level of the first driver signal to latch into a second stable state. Moreover, the synchronizer circuit includes a second pair of latches in communication with the second transmission gate. A third latch of the second pair of latches is responsive to a logic LO level of the second driver signal to latch into the first stable state. A fourth latch of the second pair of latches is responsive to a logic HI level of the second driver signal to latch into the second stable state.

An example of a method for synchronizing an input signal with a clock signal includes generating a plurality of driver signals in response to the input signal and the input clock signal. The method includes applying each driver signal to a different one of a plurality of latches. Further, the method includes if at least one latch of the plurality of latches resolves to a stable state then resolving one or more other latches of the plurality of latches into the same stable state. The method also includes providing an output signal from any one latch of the plurality of latches, the output signal being indicative of the input signal and in synchronization with the input clock signal.

### BRIEF DESCRIPTION OF THE VIEWS OF DRAWINGS

FIG. 1 illustrates a synchronizer circuit, in accordance with one embodiment;

FIG. 2 illustrates a method for synchronizing an input signal with an input clock signal, in accordance with one embodiment;

FIG. 3A illustrates an exemplary voltage transfer curve for a conventional latch, in accordance with prior art; and

FIG. 3B illustrates an exemplary voltage transfer curve for a plurality of latches, in accordance with one embodiment.

### DETAILED DESCRIPTION OF THE EMBODIMENTS

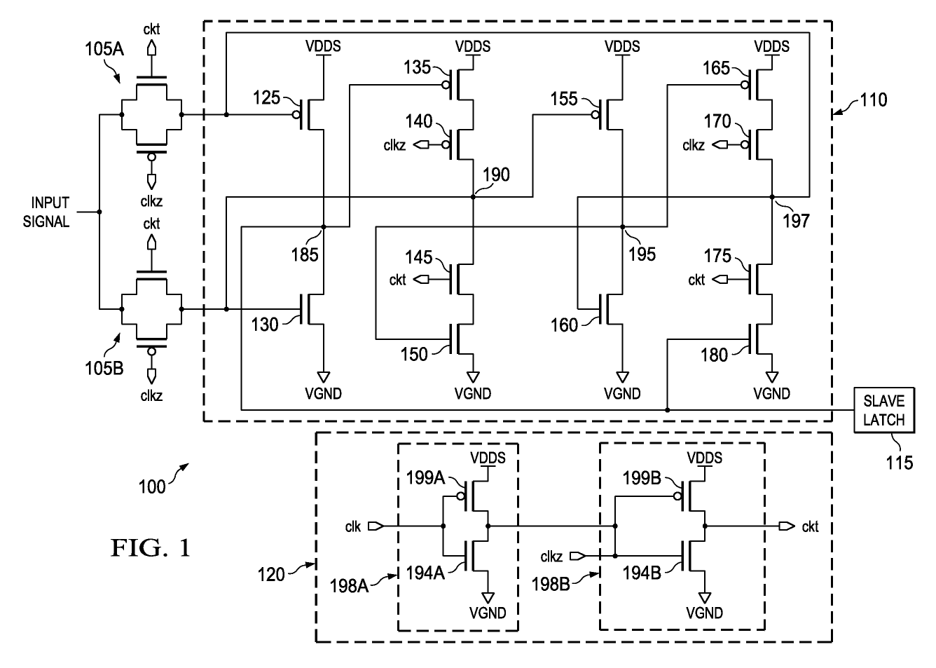

FIG. 1 illustrates a synchronizer circuit 100. The synchronizer circuit 100 includes a plurality of transmission gates, for example a transmission gate 105A and a transmission gate 105B, coupled to a master latch 110. The master latch 110 is coupled to a slave latch 115 and a clock circuit 120.

Any one of the transmission gates (105A and 105B) can be referred to as a first transmission gate or as a second transmission gate. The transmission gates (105A and 105B) receive an input signal and clock signals, and in response generate a plurality of driver signals. In some embodiments, the input signal is an asynchronous data signal which needs to be synchronized with an input clock signal. The input signal can be provided from an output of a multiplexer or a combination of logic gates. The driver signals are of unequal magnitude due to inherent parasitics. In one example, the inherent parasitics can be due to any unwanted capacitance, resistance, or inductance. The driver signals include a first driver signal and a second driver signal. The driver signal generated by the first transmission gate can be referred to as the first driver signal and the driver signal generated by the second transmission gate can be referred as the second driver signal. The transmission gate 105A is structurally identical to the transmission gate 105B to make the driver signals non-opposing. The transmission gate 105A and the transmission gate 105B generate driver signals that are of unequal magnitude, due to inherent parasitics, and hence, the transmission gates (105A and 105B) can be called substantially identical to each other. In some embodiments, each transmission gate includes a positive metal oxide semiconductor (PMOS) transistor and a negative metal oxide semiconductor (NMOS) transistor connected in parallel.

In some embodiments, a circuitry, for example an inverter circuit having size of a positive metal oxide semiconductor (PMOS) transistor skewed with respect to size of a negative metal oxide semiconductor (NMOS) transistor can be used at each input to make the driver signals unequal. The skewing is referred to as changing a transistor dimension, for example channel width and channel length.

The master latch 110 includes a plurality of stacks. Each stack includes a PMOS transistor and an NMOS transistor driven by two different signals. A first stack includes a PMOS transistor 125 and an NMOS transistor 130 with drains connected to each other. A gate of the PMOS transistor 125 is connected to the transmission gate 105A, and a source is connected to the positive power supply (VDDS). A gate of the NMOS transistor 130 is connected to the transmission gate 105B, and a source is connected to the negative power supply (VGND). A second stack includes a PMOS transistor 135, a PMOS transistor 140, an NMOS transistor 145, and an NMOS transistor 150. A drain of the PMOS transistor 135 is connected to a source of the PMOS transistor 140. A gate of the PMOS transistor 135 is connected to an output of the first stack at a node 185 and a source is connected to the VDDS. A gate of the PMOS transistor 140 is connected to a first clock signal (clkz). Drains of the PMOS transistor 140 and of the NMOS transistor 145 are connected to each other. A gate of the NMOS transistor 145 is connected to a second clock signal (ckt). A source of the NMOS transistor 145 is connected to a drain of the NMOS transistor 150. A gate of the NMOS transistor 150 is connected to an output of a third stack at a node 195. A source of the NMOS transistor 150 is connected to the VGND. The third stack includes a PMOS transistor 155 and an NMOS transistor 160 with drains connected to each other. A gate of the PMOS transistor 155 is connected to the transmission gate 105B, and a source is connected to the VDDS. A gate of the NMOS transistor 160 is connected to the transmission gate 105A, and a source is connected to the VGND. A fourth stack includes a PMOS transistor 165, a PMOS transistor 170, an NMOS transistor 175, and an NMOS transistor 180. A drain of the PMOS transistor 165 is connected to a source of the PMOS transistor 170. A gate of the PMOS transistor 165 is connected to the output of the third stack at the node 195 and a source is connected to the VDDS. A gate of the PMOS transistor 170 is connected to the first clock signal (clkz). Drains of the PMOS transistor 170 and of the NMOS transistor 175 are connected to each other. A gate of the NMOS transistor 175 is connected to the second clock signal (ckt). A source of the NMOS transistor 175 is connected to a drain of the NMOS transistor 180. A gate of the source transistor 180 is connected to the output of the first stack at the node 185. A source of the NMOS transistor 180 is connected to the VGND.

The master latch 110 includes a plurality of latches. Each latch includes a first metal oxide semiconductor (MOS) transistor driven by a driver signal and a second MOS transistor driven by an output of the first MOS transistor. In the embodiment shown in FIG. 1, there are four latches, each latch formed by a PMOS transistor of one of the stacks and an NMOS transistor of another one of the stacks in a feedback configuration. A first latch includes the PMOS transistor 125 driven by the driver signal (logic LO level) generated by the transmission gate 105A and the NMOS transistor 180 driven by output of the PMOS transistor 125. A second latch includes the NMOS transistor 160 driven by the driver signal (logic HI level) generated by the transmission gate 105A and the PMOS transistor 165 driven by output of the NMOS transistor 160. A third latch includes the PMOS transistor 155 driven by the driver signal (logic LO level) generated by the transmission gate 105B and the NMOS transistor 150 driven by output of the PMOS transistor 155. A fourth latch includes the NMOS transistor 130 driven by the driver signal (logic HI level) generated by the transmission gate 105B and the PMOS transistor 135 driven by output of the NMOS transistor 130. The first latch and the second latch can together be referred to as a first pair of latches. The third latch and the fourth latch can together be referred to as a second pair of latches. The first latch and the third latch, latch to a stable state which can be referred to as a first stable state. The second latch and the fourth latch, latch to a stable state which can be referred to as a second stable state.

The master latch 110 is responsive to the driver signals to provide an output signal indicative of the input signal and in synchronization with the input clock signal.

The working of the latches in case of no event of metastability is explained as follows. When the input signal is at logic level LO, then the first driver signal and the second driver signal are also at logic level LO. The PMOS transistor 125 is active and drives a signal at the node 185 to logic level HI. The logic level HI of the signal at the node 185 activates the NMOS transistor 180 which in turn pulls down a signal at a node 197 to logic level LO. The signal, with the logic level LO, at the node 197 is fed back to the PMOS transistor 125, thereby completing a feedback path. Similarly, the PMOS transistor 155 is active and drives a signal at the node 195 to logic level HI. The logic level HI of the signal at the node 195 activates the NMOS transistor 150 which in turn pulls down a signal at a node 190 to LO state. The signal, with the logic level LO, at the node 190 is fed back to the PMOS transistor 155, thereby completing the feedback path. The NMOS transistor 175 and the NMOS transistor 145 driven by the second clock signal (ckt) are also active.

When the input signal is at logic level HI, then the first driver signal and the second driver signal are at logic level HI. The NMOS transistor 160 is active and drives the signal at the node 195 to logic level LO. The logic level LO of the signal at the node 195 activates the PMOS transistor 165 which in turn pulls up the signal at the node 197 to logic level HI. The signal, with the logic level HI, at the node 197 is fed back to the NMOS transistor 160, thereby completing the feedback path. Similarly, the NMOS transistor 130 is active and drives the signal at the node 185 to logic level LO. The logic level LO of the signal at the node 185 activates the PMOS transistor 135 which in turn pulls up the signal at the node 190 to logic level HI. The signal, with the logic level HI, at the node 190 is fed back to the NMOS transistor 130, thereby completing the feedback path. The PMOS transistor 140 and the PMOS transistor 170 driven by the first clock signal (clkz) are also active. The output can be obtained from the node 185.

The working of the latches in case of an event of metastability is explained as follows. When the input signal is at logic level LO or at logic level HI, then logic levels of the first driver signal and the second driver signal are neither HI nor LO. The magnitude of voltages of the driver signals is a value between HI and LO. By virtue of parasitics or design, the magnitude of voltages differs by a small value. The PMOS transistor 130 and the NMOS transistor 135 are driven by the driver signals from the transmission gate 105A and the transmission gate 105B, respectively. Similarly, the NMOS transistor 165 and the PMOS transistor 160 are driven by the driver signals from the transmission gate 105A and the transmission gate 105B, respectively. The output of the PMOS transistor 130, obtained at the node 190, is fed as input to the NMOS transistor 185 and to the PMOS transistor 140. Similarly, the output of the PMOS transistor 160 obtained at the node 196 is fed as input to the PMOS transistor 170 and to the NMOS transistor 155. The output of the PMOS transistor 170 is fed back to the driver signal from the transmission gate 105A and the output from the PMOS transistor 140 is fed back to the driver signal from the transmission gate 105B, completing the feedback path in the two latches. The difference in magnitude of the driver signals from the transmission gate 105A and from the transmission gate 105B results in overall higher system gain and enables the latches to resolve faster to the stable state. The latches can resolve either to a logic level LO or to a logic level HI irrespective of the logic level of the input signal. When the master latch 110 is in metastability, the stable state can be achieved by some disturbance, for example noise, or by virtue of parasitics. This small disturbance changes the voltages of the driver signals, and due to the high gain of the latches, the master latch 110 moves away from the metastable state and settles to a valid digital logic value (HI or LO logic level). Any one latch can get resolved to the stable state first and enable other latch to enter into the same stable state.

In one example, if the latch including the PMOS transistor 130 and the NMOS transistor 185 resolves to the stable state first then the PMOS transistor 130 is active and drives the signal at the node 190 to the logic level HI, and the NMOS transistor 185 is active and drives the signal at the node 197 to the logic level LO. The signal, with the logic level LO, at the node 197 inactivates the NMOS transistor 160, and the signal, with the logic level HI, at the node 185 inactivates the PMOS transistor 135. A conflict condition can occur when the node 190 resolves to the logic level HI or the node 195 resolves to the logic level LO. However, since the PMOS transistor 135 is inactive, the node 190 cannot resolve to the logic level HI, and since the NMOS transistor 160 is inactive, the node 195 cannot resolve to the logic level LO, thereby forcing the node 190 to resolve to the logic level LO (same stable state as the node 197) and the node 195 to the logic level HI (same stable state as the node 185). Therefore, the latch including the PMOS transistor 125 and the NMOS transistor 180 enters into the stable state and then forces the latch including the PMOS transistor 155 and the NMOS transistor 150 to enter into the same stable state. Similarly, the latch including the PMOS transistor 155 and the NMOS transistor 150 can enter into a stable state first and can then force the latch including the PMOS transistor 125 and the NMOS transistor 180 to enter into the same stable state by inactivating the PMOS transistor 165 and the NMOS transistor 130.

In another example, if the latch including the NMOS transistor 130 and the PMOS transistor 135 resolves to the stable state first then the NMOS transistor 130 is active and drives the signal at the node 185 to the logic level LO, and the PMOS transistor 135 is active and drives the signal at the node 190 to the logic level HI. The signal, with the logic level LO, at the node 185 inactivates the NMOS transistor 180, and the signal, with the logic level HI, at the node 190 inactivates the PMOS transistor 155. A conflict condition occur when the node 197 resolves to the logic level LO or the node 195 resolves to the logic level HI. However, since the PMOS transistor 155 is inactive, the node 195 cannot resolve to the logic level HI, and since the NMOS transistor 180 is inactive, the node 197 cannot resolve to the logic level LO, thereby forcing the node 195 to resolve to the logic level LO (same stable state as the node 185) and the node 197 to the logic level HI (same stable state as the node 190). Therefore, the latch including the NMOS transistor 130 and the PMOS transistor 135 enters into the stable state and then forces the latch including the NMOS transistor 160 and the PMOS transistor 165 to enter into the same stable state. Similarly, the latch including the NMOS transistor 160 and the PMOS transistor 165 can enter into a stable state first and can then force the latch including the NMOS transistor 130 and the PMOS transistor 135 to enter into the same stable state by inactivating the PMOS transistor 125 and the NMOS transistor 150.

The output obtained from the node 185 can be fed to the slave latch 115 directly or through a plurality of transmission gates. The slave latch 115 can be a combination of PMOS and NMOS transistors. In some embodiments, the slave latch 115 can also include the latches and architecture of the slave latch 115 can be similar to the master latch 110.

The clock circuit 120 provides the first clock signal (clkz) and the second clock signal (ckt) in response to an input clock signal (clk). The first clock signal and the second clock signal can together be referred to as a common clock signal. The input clock signal is inverted by an inverter circuit 198A to generate the first clock signal. Further, the first clock signal is again inverted by an inverter circuit 198B to generate the second clock signal. The second clock signal is inverted and time-delayed with respect to the first clock signal. Each inverter circuit includes a PMOS transistor and an NMOS transistor. The inverter circuit 198A includes a PMOS transistor 199A and an NMOS transistor 194A with common gate supply. The inverter circuit 198B includes a PMOS transistor 199B and an NMOS transistor 194B with common gate supply. The first and second clock signals drive a plurality of PMOS transistors and a plurality of NMOS transistors of the master latch 110. The first and second clock signals are also used to control the transmission gates.

In some embodiments, NAND or NOR circuits can be connected in the feedback path or the forward path of the latches to create metastability hardened reset or preset flip flops. In one embodiment, the forward path includes the PMOS transistor 125 and the feedback path includes the NMOS transistor 180. In another embodiment, the forward path includes the PMOS transistor 155 and the feedback path includes the NMOS transistor 150. In yet another embodiment, the forward path includes the NMOS transistor 160 and the feedback path includes the PMOS transistor 165. In still another embodiment, the forward path includes the NMOS transistor 130 and the feedback path includes the PMOS transistor 135.

It is noted that FIG. 1 is explained using two latches. However, more latches can be used based on size and desired gain. If faster recovery to stable state is desired then more latches along with transmission gates or any other circuitry can be added. Any one of the latches entering into stable state first can then enable other latches to enter into the stable state.

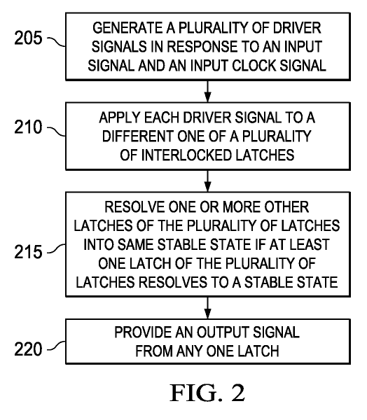

FIG. 2 illustrates a method of synchronizing an input signal with an input clock signal. At step 205, a plurality of driver signals is generated in response to the input signal and the input clock signal. In some embodiments, the input signal is an asynchronous data signal which needs to be synchronized with an input clock signal. The driver signals are unequal in magnitude and non-opposing to each other. At step 210, each driver signal is applied to a different one of a plurality of latches. Each latch includes a MOS transistor (first MOS transistor) driven by a driver signal. Further, each latch includes another MOS transistor (second MOS transistor) driven by an output of the first MOS transistor. At step 215, one or more other latches of the plurality of latches is resolved into same stable state if at least one latch of the plurality of latches resolves to a stable state.

In case of a metastability scenario, each latch can latch into either logic level LO or logic level HI irrespective of the state of the input signal. When the input signal is at logic level LO or HI then the driver signal can neither be at logic level HI nor at logic level LO. The magnitude of voltages of the driver signals is a value between HI and LO. By virtue of parasitics or design, the magnitude of voltages differs by a small value. The difference in magnitude of the driver signals results in overall higher system gain and enables the latches to resolve to the stable state. The stable state can be achieved by some disturbance, for example noise. This small disturbance changes the voltages of the driver signals, and due to the high gain of the latches, the latches moves away from the metastable state and settles to a valid digital logic value (HI or LO logic level). Any one latch can get resolved to the stable state first and enable other latch to enter into the same stable state.

At step 220, an output signal is provided from any one latch. The output signal can then be used to drive a slave latch.

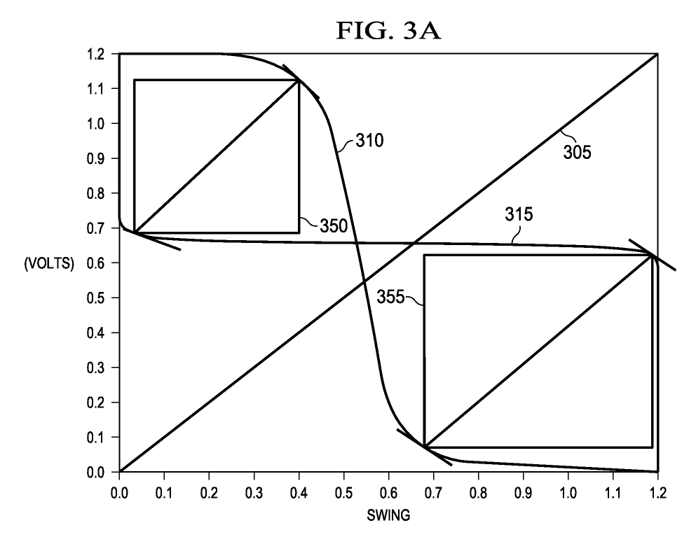

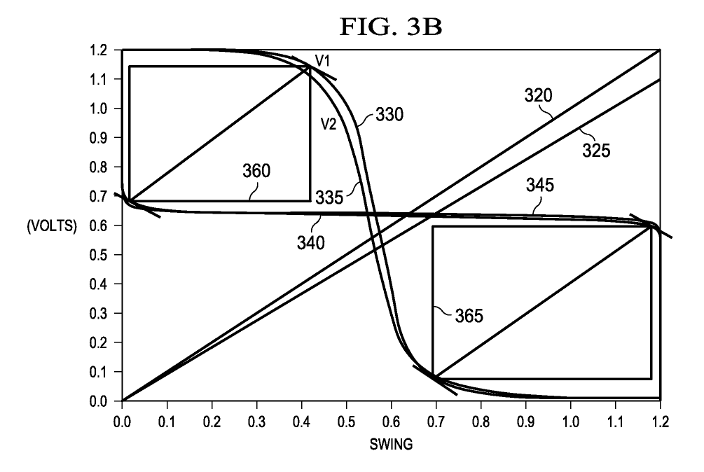

FIG. 3A is an exemplary voltage transfer curve (VTC) for a conventional latch (prior art). FIG. 3B is an exemplary VTC for a plurality of latches. The VTC indicates gain of a circuit.

In FIG. 3A, curve 305 corresponds to input voltage, and curve 310 and curve 315 corresponds to outputs of inverter circuits of the conventional latch. The conventional latch includes back-to-back connected inverter circuits. One inverter circuit is placed in the forward path and another inverter circuit in the feedback path. An output of the inverter circuit in the forward path is fed as input to the inverter circuit in the feedback path.

In FIG. 3B, curve 320 and curve 325 correspond to voltages of the unequal and non-opposing driver signals generated by the transmission gates, curve 330 and curve 335 correspond to voltages of stacks with two MOS transistors, for example the first stack (v1) and the third stack (v2), and curve 340 and curve 345 correspond to voltages of stacks with at least two MOS transistors, for example the second stack and the fourth stack.

Gain of the conventional latch can be calculated by choosing a point on the curve 310 and curve 315 where slope is “−1”. The point where the slope is “−1” is chosen to measure noise margin (NM) as the transition from one valid logic level to other starts at the point where the slope is −1. The NM is the amount by which a signal exceeds a threshold to enter into logic level HI or into logic level LO. The overall NM of a digital circuit can be determined by calculating a noise margin high (NMH) and a noise margin low (NML) for the digital circuit. The NMH and the NML can be calculated as follows:

NMH=VOH−VIH

NML=VIL−VOL

NMH of the digital circuit is the difference between high level voltage of an output signal (VOH) and the high level voltage of an input signal (VIH). NML of the digital signal is the difference between low level voltage of the input signal (VIL) and the low level voltage of the output signal (VOL).

Exemplary values of NM's of a conventional latch and the latches are given in the following tables.

TABLE 1
SNM for the Conventional latch

| Noise Margin (NM) | High (NMH) | Low (NML) | Swing (NMH − NML) |
|---|---|---|---|
| Forward path | 0.544 V | 0.396 V | 0.148 V |
| Feedback path | 0.504 V | 0.618 V | 0.114 V |

TABLE 2
SNM for the latches, v1 output

| Noise Margin (NM) | High (NMH) | Low (NML) | Swing (NMH − NML) |
|---|---|---|---|
| Forward path | 0.514 V | 0.43 V | 0.084 V |
| Feedback path | 0.52 V | 0.588 V | 0.068 V |

TABLE 3
SNM for the latches, v2 output

| Noise Margin (NM) | High (NMH) | Low (NML) | Swing (NMH − NML) |
|---|---|---|---|
| Forward path | 0.523 V | 0.403 V | 0.12 V |
| Feedback path | 0.532 V | 0.6 V | 0.068 V |

Table 1 provides values for NM's and swings of a conventional latch in the forward path and the backward path. The values in Table 1 are based on the voltage values from the curve 310 and curve 315. Table 2 and Table 3 provide values for NM's and swings of the latches. The values in Table 2 are based on the voltage values from the curve 330 and the curve 345. The values in Table 3 are based on the voltage values from the curve 335 and the curve 340. Further, Table 2 and Table 3 have matching NM values for the forward path and the feedback path as compared to that of the NM values in Table 1 of the conventional latch. Furthermore, Table 2 and Table 3 have lower swing values for the forward path and the feedback path as compared to that of the swing values in Table 1 of the conventional latch. Lower swings lead to sharper transitions between the logic levels and faster resolution to the stable state for the dual latches.

Further, by drawing a diagonal and joining the “−1” slope points on the curve 310 and curve 315, a rectangular box 350 and a rectangular box 355 can be created. Similarly, by drawing a diagonal and joining the “−1” slope points on the curve 330 and the curve 345, a rectangular box 360 and a rectangular box 365 can be created. By analyzing the rectangular box 350, the rectangular box 355, the rectangular box 360, and the rectangular box 365, the NM and gain of the convention latch and the dual latch can be determined. The closer the two rectangular boxes are, the better the match of the NM's. In other aspect, if the shape of the rectangular box 350 matches that of the rectangular box 355 then the match of the NM's is better. The rectangular box 360 and the rectangular box 365 of FIG. 3B have better match than the rectangular box 350 and the rectangular box 355 of FIG. 3A. Hence, the latches have better NM and sharper transition of logic levels than the conventional latch. Further, the gain of latches is higher than the gain of the conventional latch. The latches can resolve faster than the convention latch on account of higher gain.

Various embodiments of the present disclosure provide latches driven by driver signals that are unequal in magnitude and non-opposing to each other. This increases the probability of faster resolution and brings the synchronizer circuit out of the metastability state in a time efficient way. Moreover, order of magnitude of mean time between failures (MTBF) is also increased. For example, the MTBF in number of years for a conventional flip-flop is around 3.31E+59 years, whereas for the flop including the latches connected to different transmission gates, the MTBF is 3.62E+84 years. The order of magnitude is increased by 1.1E+25 times. The resolution time is also reduced. The resolution time is the time required by a circuit to resolve to a stable state.

In the foregoing discussion, the term “coupled or connected” refers to either a direct electrical connection between the devices connected or an indirect connection through one or more passive or active intermediary devices. The term “circuit” means at least either a single component or a multiplicity of components, either active or passive, that are connected together to provide a desired function. The term “signal” means at least one current, voltage, charge, data, or other signal.

Those skilled in the art will recognize that a wide variety of modifications, alterations, and combinations can be made with respect to the above described embodiments without departing from the scope of the present disclosure, and that such modifications, alterations, and combinations are to be viewed as being within the ambit of the present disclosure.

What is claimed is:

1. A synchronizer circuit comprising:
a plurality of transmission gates, each transmission gate of the plurality of transmission gates responsive to an input signal and a clock signal to generate a driver signal; and
a plurality of latches, a first one of the plurality of latches in electrical communication with any one transmission gate of the plurality of transmission gates and responsive to the driver signal to resolve to a stable state, and a second one of the plurality of latches in electrical communication with another transmission gate of the plurality of transmission gates and responsive to another driver signal to resolve to the same stable state.

2. The synchronizer circuit of claim 1, wherein the driver signal and another driver signal are unequal in magnitude and non-opposing to each other.

3. The synchronizer circuit of claim 1, wherein each transmission gate is substantially identical to other transmission gates.

4. The synchronizer circuit of claim 1, wherein each latch comprises:
a first metal oxide semiconductor (MOS) transistor driven by a driver signal; and
a second MOS transistor driven by an output of the first MOS transistor.

5. The synchronizer circuit of claim 1, wherein the plurality of latches are comprised in at least one of:
a master latch; and
a slave latch.

6. The synchronizer circuit of claim 1, wherein the clock signal comprises:
a first clock signal; and
a second clock signal, wherein the second clock signal is inverted and time-delayed with respect to the first clock signal.

7. The synchronizer circuit of claim 1, wherein
the first one of the plurality of latches is operative to force the second one of the plurality of latches to resolve to the same stable state, if the second one of the plurality of latches enter into a metastable state; and
the second one of the plurality of latches is operative to force the first one of the plurality of latches to resolve to the same stable state, if the first one of the plurality of latches enter into the metastable state.

8. A synchronizer circuit comprising:
a first transmission gate responsive to an input signal, and a first and second clock signals to provide a first driver signal;
a second transmission gate responsive to the input signal, and the first and second clock signals to provide a second driver signal;
a first pair of latches in communication with the first transmission gate, a first latch of the first pair of latches responsive to a logic LO level of the first driver signal to latch into a first stable state, a second latch of the first pair of latches responsive to a logic HI level of the first driver signal to latch into a second stable state; and
a second pair of latches in communication with the second transmission gate, a third latch of the second pair of latches responsive to a logic LO level of the second driver signal to latch into the first stable state, a fourth latch of the second pair of latches responsive to a logic HI level of the second driver signal to latch into the second stable state.

9. The synchronizer circuit of claim 8, wherein each latch comprises:
a first metal oxide semiconductor (MOS) transistor driven by a driver signal; and
a second MOS transistor driven by an output of the first MOS transistor.

10. The synchronizer circuit of claim 8 further comprising:
a first inverter that inverts an input clock signal to provide the first clock signal; and
a second inverter that inverts the first clock signal to provide a second clock signal, the second clock signal being inverted and time-delayed with respect to the first clock signal.

11. A method for synchronizing an input signal with an input clock signal, the method comprising:
generating a plurality of driver signals in response to the input signal and the input clock signal;
applying each driver signal to a different one of a plurality of latches;
resolving one or more other latches of the plurality of latches into same stable state, if at least one latch of the plurality of latches resolves to a stable state; and
providing an output signal from any one latch of the plurality of latches, the output signal being indicative of the input signal and in synchronization with the input clock signal.

12. The method of claim 11, wherein generating a plurality of driver signals comprises:
generating the plurality of driver signals that are unequal in magnitude and non-opposing to each other.

13. The method of claim 11, wherein applying each driver signal comprises:
driving a first metal oxide semiconductor (MOS) transistor by the driver signal; and
driving a second MOS transistor by output of the first MOS transistor.

14. The method of claim 11 further comprising:
generating the input clock signal, wherein the input clock signal comprises
a first clock signal, and
a second clock signal, wherein the second clock signal is inverted and time-delayed with respect to the first clock signal.
